(19) United States
(12) Patent Application Publication
(10) Pub. No.: US 2005/0179133 A1
(43) Pub. Date: Aug. 18, 2005

(54) Semiconductor device

(76) Inventors: Tomio Iwasaki, Tsukuba (JP); Hiroshi Moriya, Chiyoda (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/975,448

(22) Filed: Oct. 29, 2004

(30) Foreign Application Priority Data
Feb. 12, 2004 (JP) 2004-034383

(51) Int. Cl. H01L 23/48

(52) U.S. Cl. 257/758

(57) ABSTRACT

A semiconductor device provided with a mechanism for recording information is intended to provide a highly reliable one time programmable memory and to provide one time programmable memories at a high yield. In a one time programmable memory, a state in which the electrical resistance is high is varied to another state in which it is low by silicifying a metal with silicon and matching the high resistance state (a metal/silicon separated state) and the low resistance state (a silicide state) to 0 and 1, respectively, wherein there is used an underlayer material which reduces the interfacial energy in the interface with the silicide layer, which constitutes the low resistance state.

### BACKGROUND OF THE INVENTION

1. Field of the Invention

The present invention relates to a semiconductor device provided with a mechanism for recording information.

2. Description of the Related Art

Known semiconductor devices provided with a mechanism for recording information include one described in JP-A-2003-142653.

This publication describes a type of nonvolatile memory which permits programming only once (one time programmable memory) among different semiconductor memories.

As described in this publication, available programming methods include one whereby a state in which the electrical resistance is high is varied to another state in which it is low by silicifying a metal with silicon and matching the high resistance state and the low resistance state to 0 and 1, respectively.

However, the mode described in the foregoing publication involves a problem that the electrical resistance becomes rather high in the low resistance state, which may therefore become difficult to be distinguished from the high resistance state.

### BRIEF SUMMARY OF THE INVENTION

An object of the present invention, therefore, is to provide a semiconductor device that can contribute to solving the problem noted above.

The invention can provide a highly reliable semiconductor device by solving the problem noted above and having the following modes of implementation.

For a memory wherein a state in which the electrical resistance is high is varied to another state in which it is low by silicifying a metal with silicon and matching the high resistance state (a metal/silicon separated state) and the low resistance state (a silicide state) to 0 and 1, respectively, the present inventors have made earnest studies for obtaining means of improving the stability of the low resistance state, and discovered an effective solution in the use of an underlayer material which reduces the interfacial energy on the interface with the silicide layer which constitutes the low resistance state.

The problem posed to the invention under the present application can be solved by a one time programmable memory having the following configuration, for instance.

(1) A semiconductor device provided with a semiconductor substrate, a wiring formed on one main face side of the semiconductor substrate, and a memory unit communicating with the wiring, wherein the memory unit has a first electrode, a silicon film which contains silicon and is formed over the first electrode, and a second electrode formed over the silicon film, the first electrode includes at least any one of silicon, nickel silicide and cobalt silicide as its main constituent material, and the second electrode includes cobalt or nickel as its main constituent material.

The semiconductor device may be provided with a plurality of the memory units, and silicide may be formed of the second electrode and the silicon film in a prescribed one or ones of the memory units in response to recording of information.

The silicon film may contain impurities other than silicon if it has silicon as its main constituent material to allow sufficient formation of silicide.

(2) In the semiconductor device of (1) above, a dielectric film may be formed around the first electrode and the main constituent material of the dielectric film may be either hafnium oxide or zirconium oxide.

It is preferable for the main constituent material of the dielectric film to be hafnium oxide or zirconium oxide strong in (111) texture.

(3) In the semiconductor device of (1) or (2) above, a silicide layer and the silicon layer may be formed between the upper electrode and the lower electrode.

Or, the above silicide may as well be formed in a position adjacent to silicide formed by the electrodes and the silicon film.

(4) In any of the semiconductor devices of (1) through (3) above, the semiconductor substrate may be so formed that its (111) face be directed toward the main face.

(5) Or, in a semiconductor device provided with a semiconductor substrate, a wiring formed on one main face side of the semiconductor substrate, and a memory unit communicating with the wiring, wherein the memory unit has a first electrode, a silicon film which contains silicon and is formed over the first electrode, and a second electrode formed over the silicon film; it is preferable for the silicon film and the second electrode to form silicide in response to recording of information, and for the first electrode to comprise a material whose difference in lattice constant from the silicide to be formed is not more than 7%.

(6) Or, it is characterized of a semiconductor device provided with a semiconductor substrate, a wiring formed on one main face side of the semiconductor substrate, and a memory unit communicating with the wiring, wherein the memory unit has a first electrode, a silicon film which contains silicon and is formed over the first electrode, and a second electrode formed over the silicon film, the silicon film and the second electrode form silicide in response to recording of information, and a dielectric film is formed around the first electrode and the dielectric film comprises a material whose difference in lattice constant from the second electrode is not more than 7%.

(7) Or, it is characterized of a semiconductor device provided with a semiconductor substrate, a silicide film formed in contact with one main face side of the silicon substrate, a dielectric film formed in contact with the silicide film, a first electrode formed in contact with the dielectric film, a silicon film formed in contact with the first electrode, and a second electrode film formed in contact with the silicon film, wherein the dielectric film uses at least one of hafnium oxide and zirconium oxide as its main constituent material, the main constituent material of the first electrode is silicon, the main constituent material of the second electrode is at least one of cobalt and nickel, and the one main face of the silicon substrate is parallel to the (111) crystal face of silicon. Alternatively, the silicon film may be formed in contact with the main face side of the silicon substrate.

(8) Or, it is characterized of a semiconductor device provided with a semiconductor substrate, a silicide film formed in contact with one main face side of the silicon substrate, a dielectric film formed in contact with the silicide film, a first electrode formed in contact with the dielectric film, a silicon film formed in contact with the first electrode, and a second electrode film formed in contact with the silicon film, wherein the dielectric film uses at least one of hafnium oxide and zirconium oxide as its main constituent material, the main constituent material of the first electrode is at least one of cobalt silicide and nickel silicide, the main constituent material of the silicide film is at least one of cobalt silicide and nickel silicide, and the main constituent material of the second electrode is at least one of cobalt and nickel, and the one main face of the silicon substrate is parallel to the (111) crystal face of silicon. Alternatively, the silicon film may be formed in contact with the main face side of the silicon substrate.

To add, the reference here to a silicon film or a silicide film means a film whose main constituent material is silicon or silicide whichever applies, and does not exclude the presence of additional elements or the like. A main constituent material means the material whose atom element percent concentration is the highest.

The configuration described above makes it possible to solve the problem noted above, and to provide a highly reliable semiconductor device in one or another of the forms described below.

For instance, a highly reliable one time programmable memory can be provided. Further, one time programmable memories can be provided at a high yield.

According to the present invention, it is possible to form a semiconductor device which can solve the problem unsolved by the prior art. It is thereby made possible to provide a highly reliable semiconductor device having an information recording unit.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWINGS

FIG. 1 shows a section of a main part of a one time programmable memory, which is a first preferred embodiment according to the present invention.

FIG. 2 shows a section of the main part of the one time programmable memory, which is the first preferred embodiment according to the invention, after programming.

FIG. 3 is a graph showing how, where cobalt is used for an upper electrode 6 and cobalt silicide is used for a silicide 7, the diffusion coefficient of cobalt is dependent on the combination of a lower electrode 4/SiO₂/(100)Si.

FIG. 4 is a graph showing how, where cobalt is used for the upper electrode 6 and cobalt silicide is used for the silicide 7, the diffusion coefficient of cobalt is dependent on the combination of the lower electrode 4/dielectric 3/(100)Si substrate.

FIG. 5 is a graph showing how, where cobalt is used for the upper electrode 6 and cobalt silicide is used for the silicide 7, the diffusion coefficient of cobalt is dependent on the combination of the lower electrode 4/dielectric 3/(111)Si substrate.

FIG. 6 is a graph showing how, where nickel is used for the upper electrode 6 and nickel silicide is used for the silicide 7, the diffusion coefficient of nickel is dependent on the combination of the lower electrode 4/SiO₂/(100)Si.

FIG. 7 is a graph showing how, where nickel is used for the upper electrode 6 and nickel silicide is used for the silicide 7, the diffusion coefficient of nickel is dependent on the combination of the lower electrode 4/dielectric 3/(100)Si substrate.

FIG. 8 is a graph showing how, where nickel is used for the upper electrode 6 and nickel silicide is used for the silicide 7, the diffusion coefficient of nickel is dependent on the combination of the lower electrode 4/dielectric 3/(111)Si substrate.

FIG. 9 shows a section of a main part of a one time programmable memory, which is a second preferred embodiment according to the invention.

FIG. 10 shows a section of a main part of a one time programmable memory, which is a third preferred embodiment according to the invention.

FIG. 11 shows a section of the main part of the one time programmable memory, which is the third preferred embodiment according to the invention, after programming.

FIG. 12 shows the sectional structure of the main part of a silicidation memory using a transistor for memory cell selection.

FIG. 13 shows the circuit structure of the silicidation memory using the transistor for memory cell selection.

FIG. 14 shows the circuit structure of a silicidation memory using a diode for memory cell selection.

FIG. 15 shows the sectional structure of the main part of the silicidation memory using the diode for memory cell selection.

FIG. 16 is a block diagram of a SRAM memory chip equipped with a defect relieving circuit.

### DETAILED DESCRIPTION OF THE INVENTION

Preferred embodiments of the present invention will be described in detail below with reference to the accompanying drawings. The application of the invention, however, is not limited to these embodiments, and in no way precludes any appropriate addition or modification based on known art.

The embodiments described below are semiconductor devices each provided with a one time programmable memory as preferable such semiconductor devices.

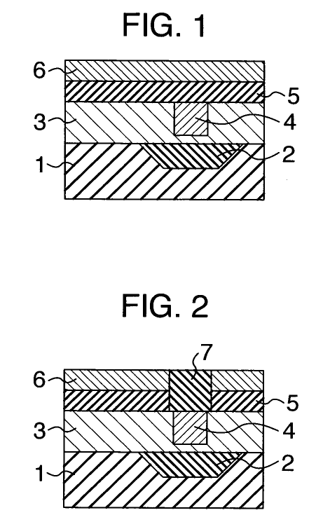

First, the sectional structure of the main part of a one time programmable memory, which is a first preferred embodiment according to the invention, is shown in FIG. 1. The one time programmable memory of this embodiment, as shown in FIG. 1, is provided with a silicon substrate 1, for instance, as the semiconductor substrate. Over this silicon substrate 1, an impurity diffusion layer 2 is formed as an interconnect layer. The memory has a configuration in which a dielectric 3 is formed over the impurity diffusion layer 2, a lower electrode 4 is surrounded with the dielectric 3, a silicon film 5 is formed over the lower electrode, and an upper electrode 6 is formed over the silicon film 5, in this order. These elements are fabricated by, for instance, sputtering, chemical vapor deposition (CVD) or plating.

The lower electrode 4 is formed by a method of forming a hole after the dielectric 3 is formed and filling this hole with silicon, or the like. In this drawing, the lower electrode 4 and the impurity diffusion layer 2, which is the interconnect layer, are arranged interposing part of the dielectric film. The thickness of the dielectric 3 over the impurity diffusion layer is less there than it is around the lower electrode 4. Though the lower electrode 4 and the impurity layer 2 may be in direct contact with each other, it is more preferable for the hardly heat-transferable dielectric material to intervene to an extent that it can somehow conduct electricity in order that the silicon film 5 and the upper electrode 6 can accumulate sufficient heat to let siliciding reaction occur. Programming is accomplished by causing the silicon film 5 and the upper electrode 6 to give rise to the siliciding reaction by utilizing the heat resulting from the electricity conduction, and thereby forming silicide 7. The state after the memory is programmed is shown in FIG. 2.

In this embodiment, by using for the lower electrode 4 a material which would reduce the interfacial energy in the interface between the silicide 7 and the lower electrode 4, the silicide 7 can be prevented from increasing its resistance. More specifically, where the main constituent material of the upper electrode 6 is cobalt or nickel, the resistance is prevented from increasing by using for the lower electrode 4 a material which would reduce the interfacial energy of the lower electrode 4 in its interface with the silicide 7, which is either cobalt silicide or nickel silicide.

For this reason, a material whose lattice mismath with silicide is no more than 7% is used for the lower electrode 4. If the silicide 7 is either cobalt silicide or nickel silicide, the lower electrode 4 should be at least one of silicon, cobalt silicide and nickel silicide. It is desirable in addition for the material to excel in crystallinity (highly regular in atomic arrangement).

In order to improve the crystallinity of the lower electrode 4 comprising at least one of silicon, cobalt silicide and nickel silicide, it is desirable to use a material close to silicon, cobalt silicide or nickel silicide in crystal structure as the main constituent material of the dielectric 3 adjoining the lower electrode 4. More specifically, the desirable material is hafnium oxide or zirconium oxide. Still more desirably, the lower electrode 4 should be made of a silicon having a strong (111) texture, a cobalt silicide having a strong (111) texture, or a nickel silicide having a strong (111) textrue. In this connection, the desirable main constituent material of the dielectric 3 is a hafnium oxide or a zirconium oxide having a strong (111) texture.

A silicon having a strong (111) texture in this context means, for instance, that the quotient of division of the (111) diffraction peak intensity determined by X-ray diffractometry by the (220) diffraction peak intensity is not less than 2. It is more preferable for this value to be not less than 3. For non-oriented silicon, the quotient of division of the (111) diffraction peak intensity by the (220) diffraction peak intensity is about 1.8. A cobalt silicide having a strong (111) texture means, for instance, that the quotient of division of the (111) diffraction peak intensity determined by X-ray diffractometry by the (220) diffraction peak intensity is not less than 1. It is more preferable for this value to be not less than 2. For non-oriented cobalt silicide, the quotient of division of the (111) diffraction peak intensity by the (220) diffraction peak intensity is about 0.9. A nickel silicide having a strong (111) texture means, for instance, that the quotient of division of the (111) diffraction peak intensity determined by X-ray diffractometry by the (220) diffraction peak intensity is not less than 1.2. It is more preferable for this value to be not less than 2. For non-oriented nickel silicide, the quotient of division of the (111) diffraction peak intensity by the (220) diffraction peak intensity is about 1. A hafnium oxide having a strong (111) texture means, for instance, that the quotient of division of the (111) diffraction peak intensity determined by X-ray diffractometry by the (220) diffraction peak intensity is not less than 2. It is more preferable for this value to be not less than 3. For non-oriented hafnium oxide, the quotient of division of the (111) diffraction peak intensity by the (220) diffraction peak intensity is about 1.3. A zirconium oxide having a strong (111) texture means, for instance, that the quotient of division of the (111) diffraction peak intensity determined by X-ray diffractometry by the (220) diffraction peak intensity is not less than 3. It is more preferable for this value to be not less than 4. For non-oriented zirconium oxide, the quotient of division of the (111) diffraction peak intensity by the (220) diffraction peak intensity is about 2.5. These values hardly vary even if any additional element or impurity element is contained.

It is further desirable to use a silicon substrate (hereinafter referred to as (111) Si substrate) whose surface is oriented to a crystal face parallel to the (111) crystal face, because this would contribute to improving the texture of the dielectric film. This makes it possible to strengthen the (111) texture of the hafnium oxide or zirconium oxide, and thereby to enhance stability.

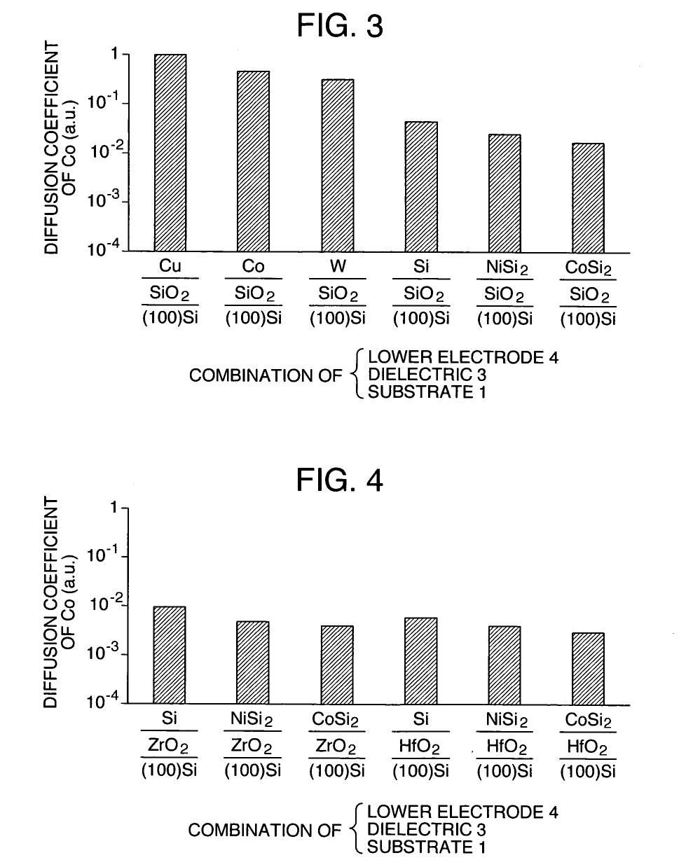

With a view to demonstrating the effect of the silicide 7 mainly comprising cobalt silicide to prevent the resistance from increasing, the diffusion coefficient of cobalt atoms in the silicide 7 was calculated by molecular dynamic simulation. A method of calculating the diffusion coefficient by molecular dynamic simulation is described in, for instance, Physical Review B, vol. 29 (1984), pp. 5367-5369. It is shown that the smaller the diffusion coefficient of cobalt atoms is, the more difficult it is for the cobalt atoms to move, and accordingly, they are stable and it is difficult for them to increase in resistance. If the diffusion coefficient of cobalt atoms is high, the cobalt atoms will move away and the cobalt concentration will become locally thin, resulting in an increased resistance. Calculated results at room temperature are shown in FIG. 3 through FIG. 5. In these graphs, cases in which Cu/SiO₂/(100)Si is used as the combination of lower electrode 4/dielectric 3/substrate 1 are standardized at a cobalt diffusion coefficient of 1.

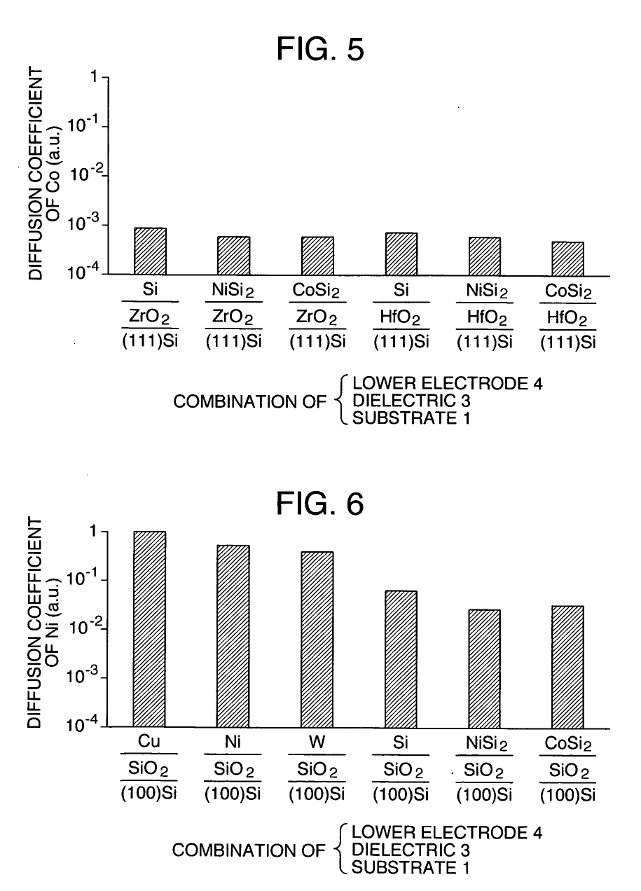

It is seen from FIG. 3 that it is preferable to use one of silicon, cobalt silicide and nickel silicide as the main constituent material of the lower electrode 4 than to use tungsten or cobalt as the main constituent material of the lower electrode 4, because the diffusion coefficient of cobalt atoms in the silicide 7 can be thereby reduced. More preferably, it should be cobalt silicide or nickel silicide to match the silicide that is to be formed. Still more preferably, it should be a silicide having the same composition as the silicide that is to be formed. Also, it is seen from FIG. 4 that it is preferable to use as the main constituent material of the dielectric 3 a material close to silicon, cobalt silicide or nickel silicide in crystal structure (hafnium oxide or zirconium oxide). It is further seen from FIG. 5 that, in order to strengthen the (111) texture of the lower electrode 4, a (111) Si substrate should be used. Incidentally, where the underlayer of the lower electrode is not a. Si substrate but a layer formed over the substrate, the film thickness of the lower electrode should be 4 nanometers or more with a view to easing the influence on the state of texture to the lower electrode side from the texture of its own underlayer member and keeping the state satisfactory.

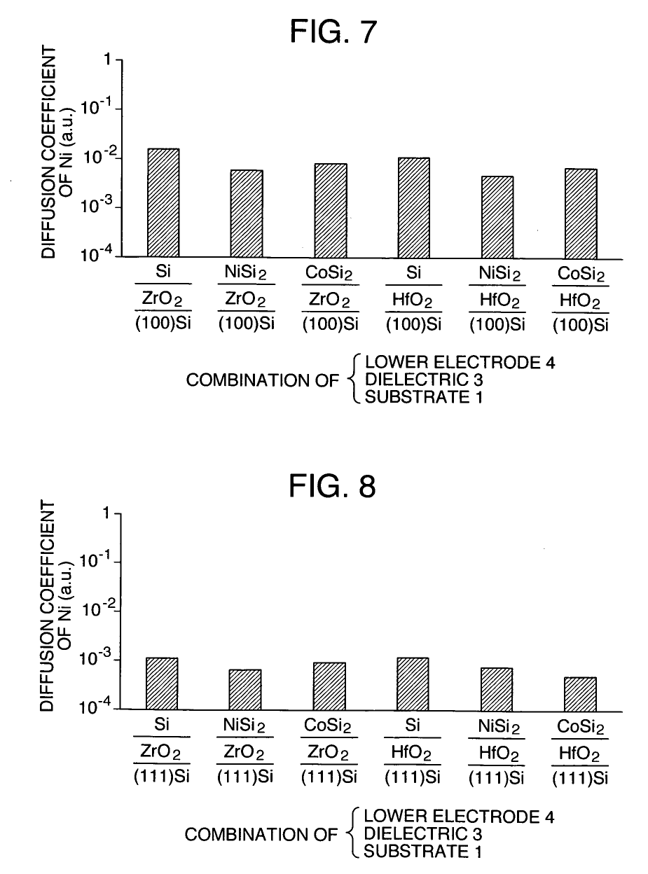

Next will be demonstrated the effect of use of nickel silicide in the same way as in the case of cobalt silicide discussed above. In this case, too, it is seen that the lower the diffusion coefficient of nickel atoms in nickel silicide is, the more difficult it is for the nickel atoms to move, and accordingly they are stable and it is difficult for them to increase in resistance. Calculated results at room temperature are shown in FIG. 6 through FIG. 8. In these graphs, cases in which Cu/SiO₂/(100)Si is used as the combination of lower electrode 4/dielectric 3/substrate 1 are standardized at a nickel diffusion coefficient of 1. It is seen from FIG. 6 that it is preferable to use one of silicon, cobalt silicide and nickel silicide as the main constituent material of the lower electrode 4 than to use tungsten or nickel as the main constituent material of the lower electrode 4, because the diffusion coefficient of cobalt atoms in the silicide 7 can be thereby reduced. More preferably, it should be cobalt silicide or nickel silicide to match the silicide that is to be formed. Still more preferably, it should be a silicide having the same composition as the silicide that is to be formed. As seen from FIG. 7, it is preferable to use as the main constituent material of the dielectric 3 a material close to silicon, cobalt silicide or nickel silicide in crystal structure (hafnium oxide or zirconium oxide). It is further seen from FIG. 8 that, in order to strengthen the (111) texture of the lower electrode 4, a (111)Si substrate should be used.

To add, the actions illustrated in the graphs seem to suggest that not only a material comprising any of silicon, cobalt silicide and nickel silicide but also some other material also containing any impurity element may be used, if only it contains one of the three as its main constituent material, which has substantial actions.

Further, to rephrase the expression of the form described above as a preferable form, it is a form in which the difference in lattice constant between the lower electrode and the silicide formed of the upper electrode and the silicide film is smaller than the difference in lattice constant between the lower electrode and the silicide film. Further, to focus on the relationship to the dielectric film formed around the lower electrode, it is a form in which the difference in lattice constant between the dielectric film and the silicide that is formed is smaller than the difference in lattice constant between the dielectric film and the silicide film.

In one of the specific preferable forms, the silicide film formed by the aforementioned silicidation (the cobalt silicide film in the cobalt upper electrode) should preferably be in a state in which a high (111) texture silicide, such as cobalt silicide, is formed over a high (111) texture hafnium oxide film in its underlayer. Or, in terms of the relationship to its underlayer, it can be a structure in which the high (111) texture hafnium oxide is formed over a (111) silicon semiconductor substrate, with its (111) face being formed on the semiconductor substrate surface side.

Further in order to achieve true effectiveness, it is preferable for the dielectric film 3 and the lower electrode 4 formed over the silicon substrate 1 to be in contact with each other. It is also preferable for the lower electrode and the silicon film 5 to be in contact with each other. So is for the silicon film 5 and the upper electrode 6.

The contact in this context can be regarded as a state in which, for instance, films are arranged adjacent to each other via an interface.

Thus, in this mode of implementing the invention, it is possible to provide a highly reliable semiconductor device having an information recording unit. In particular, the invention can provide a suitable one time programmable memory. It can also provide one time programmable memories at a high yield.

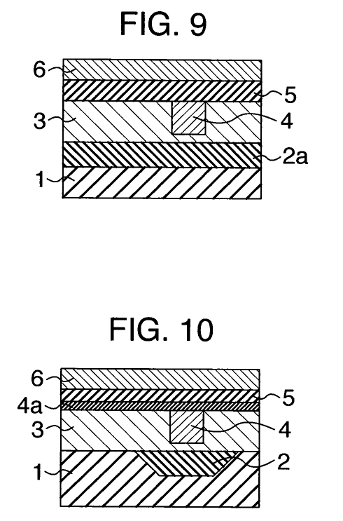

Now, the sectional structure of the main part of a one time programmable memory, which is a second preferred embodiment of the invention, is shown in FIG. 9. This embodiment, though it can have basically the same configuration as the first embodiment, differs from the first embodiment in that a wiring film 2a having any one of silicon, cobalt silicide and nickel silicide as its main constituent material as the interconnect layer, instead of the impurity diffusion layer 2 formed over the substrate 1, is formed over a substrate. The wiring film 2a has an advantage of reducing disturbances in lattice structure more than the impurity diffusion layer 2 can. Therefore, a more stable device can be configured.

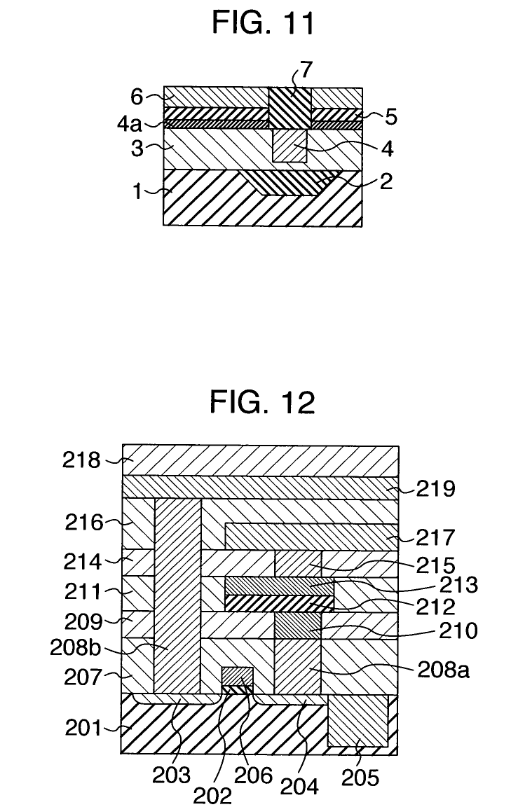

Next, the sectional structure of the main part of a one time programmable memory, which is a third preferred embodiment of the invention, is shown in FIG. 10. This embodiment, though it can have basically the same configuration as the first embodiment, differs from the first embodiment in that silicide 4a is formed underneath the silicon film 5. This provides an advantage of further increasing the stability of the silicide 7 in a state after programming has been executed (FIG. 11).

It is more preferable for the silicide formed in the area between the lower electrode and the upper electrode to have the same composition as the silicide 7 formed by programming. For instance where the silicide 7 is cobalt silicide, it should preferably be cobalt silicide or, where the silicide 7 is nickel silicide, it should preferably be nickel silicide.

Now, the sectional structure of the main part of a one time programmable memory, which is a fourth preferred embodiment of the invention, is shown in FIG. 12. The forms described with reference to the first through third embodiments can be incorporated in this embodiment. The form shown in FIG. 12 has a silicon substrate 201, which is a semiconductor substrate, a gate electrode 206 formed on one main face side of the semiconductor substrate 201 via a gate insulating film 202, and diffusion layers 203 and 204, which are source drain areas formed to match it. Reference numeral 205 denotes an element separating film. The one time programmable memory further has a dielectric film formed over the source drain areas and a memory unit formed over it and electrically communicating with the source drain areas. The memory unit has a lower electrode 210 as the first electrode, a silicon film 212 formed over it and including silicon, and an upper electrode 213 as the second electrode formed over that silicone film. As detailed configuration of the memory unit, the form disclosed with reference to the foregoing embodiments can be used.

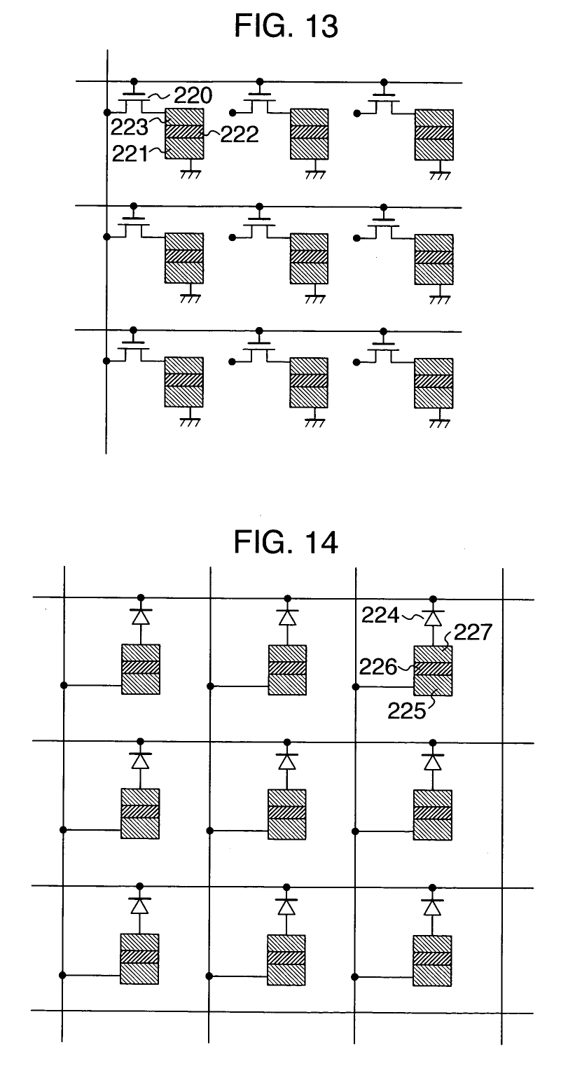

More specifically, in the one time programmable memory of this embodiment, for instance, the gate insulating film 202 and the gate electrode 206 constituting a transistor formed over the silicon substrate 201, the diffusion layers 203 and 204 matching the gate electrode are formed, and wirings are formed in them. There are configures wirings 208a, 208b, 215, 217 and 219 and the memory unit which communicates with the transistor via the wirings. The memory unit has the lower electrode 210, the silicon film 212 and the upper electrode 213. They are partitioned by dielectrics 207, 209, 211, 214, 216 and 218. Referring to FIG. 12, the transistor comprising the gate electrode 206, the gate insulating film 202 and the substrate 201 corresponds to one of the transistors in a memory circuit shown in FIG. 13. For instance, electrodes 221 and 223 between which a silicon film 222 is arranged shown in FIG. 13 can be turned on and off with a transistor 220, and can access a memory cell of a designated address. This structure can be similar to what is shown in FIG. 3 of JP-A-2003-229538.

One of the principal advantages of this embodiment consists, similarly to what was described with respect to the first embodiment, in that the resistance of the silicide can be prevented from increasing by using a material which would reduce the interfacial energy in the interface between the silicide and the lower electrode 210 for the lower electrode 210. More specifically, where the main constituent material of the upper electrode 213 is either cobalt or nickel, the resistance is prevented from increasing by using a material which would reduce the interfacial energy in the interface between the silicide, which is either cobalt silicide or nickel silicide, and the lower electrode 210 for the lower electrode 210. Where the silicide is either cobalt silicide or nickel silicide, it is desirable for the lower electrode 210 to be made of any one of silicon, cobalt silicide and nickel silicide and to excel in crystallinity (highly regular in atomic arrangement). In order to improve the crystallinity of the lower electrode 210 comprising any one of silicon, cobalt silicide and nickel silicide, it is desirable to use a material close in crystal structure to silicon, cobalt silicide or nickel silicide as the main constituent material for the dielectric 209 adjacent thereto. More specifically, the desirable material is hafnium oxide or zirconium oxide. Still more desirably, the lower electrode 210 should be made of any one of silicon strong in (111) texture, cobalt silicide strong in (111) texture and nickel silicide strong in (111) texture. To this end, it is desirable to use hafnium oxide or zirconium oxide strong in (111) texture as the main constituent material of the dielectric 209. In order to strengthen the (111) texture of hafnium oxide or zirconium oxide, it is desirable to use a silicon substrate (hereinafter referred to as (111) Si substrate) whose surface is parallel to the (111) crystal face.

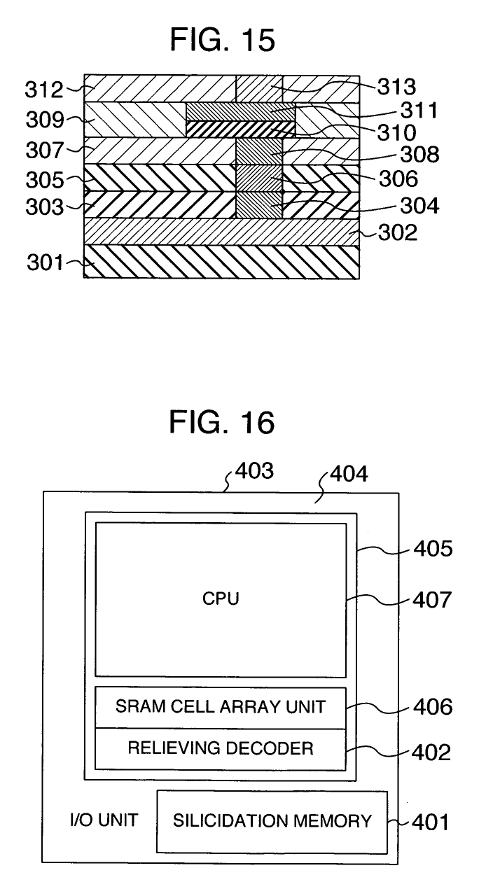

Or, the circuit structure using a transistor as shown in FIG. 13 can be replaced by a structure using a diode 224 for selecting a memory cell as shown in FIG. 14. In FIG. 14, reference numerals 225 and 227 denote electrodes, and 226, a silicide film. This structure can be similar to what is illustrated, for instance, in FIG. 1 of JP-A-2001-127263. The sectional structure of the main part in this case can be similar to structures shown in FIG. 3 or FIG. 7 of this patent publication. One example of sectional structure is shown in FIG. 15. The structure shown in FIG. 15 has a silicon substrate 301, which is a semiconductor substrate, an interconnect layer 302 formed over one main face side of that semiconductor substrate 301, a diode unit electrically communicating with that interconnect layer 302, and a memory unit electrically communicating with the diode unit.

As detailed configuration of the memory unit, the form disclosed with reference to the foregoing embodiments can be used.

More specifically, the interconnect layer 302 is formed over the substrate 301, semiconductor films 303 and 305 comprising polycrystalline silicon are formed over it, and a dielectric 307, a lower electrode 308, a dielectric 309, a silicon film 310, an upper electrode 311, a dielectric 312 and a wiring 313 are further formed. A diode for selecting a memory cell constitutes a rectifying unit. For instance, an n⁺-type region 304 is formed by ion injection of n-type impurities into the semiconductor film 303, and a p⁺-type region 306 is formed by ion injection of p-type impurities into the semiconductor film 305.

One of the principal advantages of this embodiment here again consists, similarly to what was described with respect to the first embodiment, in that the resistance of the silicide can be prevented from increasing by using a material which would reduce the interfacial energy in the interface between the silicide and the lower electrode 308 for the lower electrode 308. More specifically, where the main constituent material of the upper electrode 311 is either cobalt or nickel, the resistance is prevented from increasing by using a material which would reduce the interfacial energy in the interface between the silicide, which is either cobalt silicide or nickel silicide, and the lower electrode 308 for the lower electrode 308. Where the silicide is either cobalt silicide or nickel silicide, it is desirable for the lower electrode 308 to comprise any one of silicon, cobalt silicide and nickel silicide and to excel in crystallinity (highly regular in atomic arrangement). In order to improve the crystallinity of the lower electrode 308 comprising any one of silicon, cobalt silicide and nickel silicide, it is desirable to use a material close in crystal structure to silicon, cobalt silicide or nickel silicide as the main constituent material for the dielectric 307 adjacent thereto. More specifically, the desirable material is hafnium oxide or zirconium oxide. Still more desirably, the lower electrode 308 should be made of any one of silicon strong in (111) texture, cobalt silicide strong in (111) texture and nickel silicide strong in (111) texture. To this end, it is desirable to use hafnium oxide or zirconium oxide strong in (111) texture as the main constituent material of the dielectric 307. In order to strengthen the (111) texture of hafnium oxide or zirconium oxide, it is desirable to use a silicon substrate (hereinafter referred to as (111)Si substrate) whose surface is parallel to the (111) crystal face.

For instance, in JP-A-2001-229690, there is described a semiconductor device having an arrangement for storing relief address information and trimming information in a nonvolatile memory, such as a flash memory. If a semiconductor device is configured by using a silicidation memory described with reference to the foregoing embodiments as this nonvolatile memory, a reliable device having the above-described advantages can be obtained. An example of circuitry for such a semiconductor device is shown in FIG. 16. This example is a SRAM memory equipped with a defect relieving circuit. In FIG. 16, reference numeral 403 denotes a chip; 401, a silicidation memory as a program element; 402, a relieving decoder; 404, an input/output unit (I/O unit); and 405, a core unit. The core unit 405 includes a CPU 407 and a SRAM cell array unit 406. It is preferable for the silicidation memory program element 401 to be disposed within the I/O unit 404 with a view to saving space.

The advantages so far described can be similarly achieved even if the calculating conditions of molecular dynamic simulation are altered.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor device provided with a semiconductor substrate, an interconnect formed on one main face side of said semiconductor substrate, and a memory unit communicating with said interconnect, wherein:
said memory unit has a first electrode, a silicon film which includes silicon and is formed over said first electrode, and a second electrode formed over said silicon film, and
said first electrode includes at least any one of silicon, nickel silicide and cobalt silicide as its main constituent material, and said second electrode includes cobalt or nickel as its main constituent material.

2. The semiconductor device as claimed in claim 1, wherein a dielectric film is formed around said first electrode and the main constituent material of said dielectric film is either hafnium oxide or zirconium oxide.

3. The semiconductor device as claimed in claim 1, wherein a silicide layer and said silicon layer are formed between said upper electrode and lower electrode.

4. The semiconductor device as claimed in claim 1, wherein said semiconductor substrate is so formed that its (111) face is directed toward said main face.

5. A semiconductor device having a semiconductor substrate, a gate electrode formed on one main face side of said semiconductor substrate via a gate insulating film, a source drain area formed to match said gate electrode,
a dielectric film formed over said source drain area, and
a memory unit formed over said dielectric film and electrically communicating with said source drain area, wherein:
said memory unit has a first electrode, a silicon film which includes silicon and is formed over said first electrode, and a second electrode formed over said silicon film, and
said first electrode includes at least any one of silicon, nickel silicide and cobalt silicide as its main constituent material, and said second electrode includes cobalt or nickel as its main constituent material.

6. A semiconductor device a semiconductor substrate, an interconnect layer formed on one main face side of said semiconductor substrate, a rectifying unit electrically communicating with said interconnect layer, and a memory unit electrically communicating with said rectifying unit, wherein:
said memory unit has a first electrode, a silicon film which includes silicon and is formed over said first electrode, and a second electrode formed over said silicon film, and
said first electrode includes at least any one of silicon, nickel silicide and cobalt silicide as its main constituent material, and said second electrode includes cobalt or nickel as its main constituent material.

7. A semiconductor device provided with a semiconductor substrate, a wiring formed on one main face side of said semiconductor substrate, and a memory unit communicating with said wiring, wherein:
said memory unit has a first electrode, a silicon film which includes silicon and is formed over said first electrode, and a second electrode formed over said silicon film,
said silicon film and said second electrode form silicide in response to recording of information, and
said first electrode comprises a material whose difference in lattice constant from said silicide to be formed is not more than 7%.

8. A semiconductor device provided with a semiconductor substrate, a wiring formed on one main face side of said semiconductor substrate, and a memory unit communicating with said wiring, wherein:
said memory unit has a first electrode, a silicon film which includes silicon and is formed over said first electrode, and a second electrode formed over said silicon film,
said silicon film and said second electrode form silicide in response to recording of information, and
a dielectric film is formed around said first electrode and said dielectric film comprises a material whose difference in lattice constant from said second electrode is not more than 7%.

9. A semiconductor device provided with a semiconductor substrate, a wiring formed on one main face side of said semiconductor substrate, and a memory unit communicating with said wiring, wherein:
said memory unit has a first electrode, a silicon film which includes silicon and is formed over said first electrode, and a second electrode formed over said silicon film, and
said silicon film and said second electrode form silicide in response to recording of information, and
difference in lattice constant between said first electrode and said silicide to be formed is smaller than difference in lattice constant between said first electrode and said silicide film.

10. A semiconductor device provided with a semiconductor substrate, a wiring formed on one main face side of said semiconductor substrate, and a memory unit communicating with said wiring, wherein:
said memory unit has a first electrode, a silicon film which includes silicon and is formed over said first electrode, and a second electrode formed over said silicon film, and
said silicon film and said second electrode form silicide in response to recording of information, and
a dielectric film is formed around said first electrode and difference in lattice constant between said dielectric film and said silicide to be formed is smaller than difference in lattice constant between said dielectric film and said silicide film.
